(19) United States
(12) Patent Application Publication
(10) Pub. No.: US 2023/0098683 A1
(43) Pub. Date: Mar. 30, 2023

(54) DETERMINING A DIMENSION ASSOCIATED WITH A WELLBORE

(71) Applicant: REVEAL ENERGY SERVICES, INC., Houston, TX (US)

(72) Inventor: Erica Wilhelmina Catharina COENEN, Houston, TX (US)

(21) Appl. No.: 17/906,044

(22) PCT Filed: Mar. 12, 2021
(86) PCT No.: PCT/US2021/022205

§ 371 Date: Sep. 9, 2022

Related U.S. Application Data
(60) Provisional application No. 62/989,547, filed on Mar. 13, 2020.

(51) Int. Cl. E21B 43/26

(52) U.S. Cl. CPC E21B 43/26; E21B 2200/20

(57) ABSTRACT

Techniques for determining a geologic parameter include determining, with an analytical solution, a change to at least one control point of a boundary of a control volume defined in a subterranean formation that is caused by a hydraulic fracture formed in or adjacent the subterranean formation; determining, with a numerical solution, a fluid pressure change of the control volume based on the change to the at least one control point; and determining, with a solver, at least one dimension of at least one of the control volume or the hydraulic fracture based at least in part on the determined fluid pressure change of the control volume.

### CLAIM OF PRIORITY

This application claims priority to U.S. Patent Application No. 62/989,547 filed on Mar. 13, 2020, the entire contents of which are hereby incorporated by reference.

### TECHNICAL FIELD

This specification relates to systems and method for determining a dimension associated with a wellbore.

### BACKGROUND

Certain geologic formations, such as unconventional reservoirs in shale, sandstone, and other rock types, often exhibit increased hydrocarbon production subsequent to one or more completion operations being performed. One such completion operation may be a hydraulic fracturing operation, in which a liquid is pumped into a wellbore to contact the geologic formation and generate fractures throughout the formation due to a pressure of the pumped liquid (e.g., that is greater than a fracture pressure of the rock formation). In some cases, an understanding of a size or other characteristics of the generated hydraulic fractures may be helpful in understanding a potential hydrocarbon production from the geologic formation.

### SUMMARY

In a general implementation according to the present disclosure, a computer-implemented method includes determining, with an analytical solution executed by one or more hardware processors, a change to at least one control point of a boundary of a control volume defined in a subterranean formation, the change to the at least one control point caused by a hydraulic fracture formed in or adjacent the subterranean formation; determining, with a numerical solution executed by the one or more hardware processors, a fluid pressure change of the control volume based on the change to the at least one control point; and determining, with a solver executed by the one or more hardware processors, at least one dimension of at least one of the control volume or the hydraulic fracture based at least in part on the determined fluid pressure change of the control volume.

In an aspect combinable with the general implementation, the change to the at least one control point includes a displacement field.

In another aspect combinable with any one of the previous aspects, determining the fluid pressure change of the control volume based on the change to the at least one control point includes evaluating, with the one or more hardware processors, a displacement vector of the displacement field; and determining, with the one or more hardware processors, the fluid pressure change of the control volume based on the evaluation of the displacement vector.

In another aspect combinable with any one of the previous aspects, the at least one control point defines at least one displacement on the boundary of the control volume.

In another aspect combinable with any one of the previous aspects, the at least one control point includes a plurality of control points that define the displacement field.

In another aspect combinable with any one of the previous aspects, the change to the at least one control point includes a stress field.

In another aspect combinable with any one of the previous aspects, determining the fluid pressure change of the control volume based on the change to the at least one control point includes evaluating, with the one or more hardware processors, a stress tensor of the stress field; and determining, with the one or more hardware processors, the fluid pressure change of the control volume based on the evaluation of the stress tensor.

In another aspect combinable with any one of the previous aspects, the at least one control point defines at least one stress on the boundary of the control volume.

In another aspect combinable with any one of the previous aspects, the at least one control point includes a plurality of control points that define the stress field.

In another aspect combinable with any one of the previous aspects, the change to the at least one control point includes a strain field.

In another aspect combinable with any one of the previous aspects, determining the fluid pressure change of the control volume based on the change to the at least one control point includes evaluating, with the one or more hardware processors, a strain tensor of the strain field; and determining, with the one or more hardware processors, the fluid pressure change of the control volume based on the evaluation of the strain tensor.

In another aspect combinable with any one of the previous aspects, the at least one control point defines at least one strain on the boundary of the control volume.

In another aspect combinable with any one of the previous aspects, the at least one control point includes a plurality of control points that define the strain field.

In another aspect combinable with any one of the previous aspects, the change to the at least one control point includes a traction field.

In another aspect combinable with any one of the previous aspects, determining the fluid pressure change of the control volume based on the change to the at least one control point includes evaluating, with the one or more hardware processors, a traction vector of the traction field; and determining, with the one or more hardware processors, the fluid pressure change of the control volume based on the evaluation of the traction vector.

In another aspect combinable with any one of the previous aspects, the at least one control point defines at least one traction on the boundary of the control volume.

In another aspect combinable with any one of the previous aspects, the at least one control point includes a plurality of control points that define the traction field.

In another aspect combinable with any one of the previous aspects, the control volume includes at least a portion of a wellbore formed from a terranean surface to the subterranean formation, and the wellbore is fluidly sealed from the hydraulic fracture.

In another aspect combinable with any one of the previous aspects, the at least one control point includes a plurality of control points representative of a plurality of displacements on a boundary of the portion of the wellbore.

In another aspect combinable with any one of the previous aspects, the wellbore includes a first wellbore, and the hydraulic fracture formed in or adjacent the subterranean formation emanates from a second wellbore different than the first wellbore.

In another aspect combinable with any one of the previous aspects, the at least one dimension of the hydraulic fracture includes at least one of a half-length of the hydraulic fracture, a length of the hydraulic fracture, a half-height of the hydraulic fracture, or a height of the hydraulic fracture.

In another aspect combinable with any one of the previous aspects, the hydraulic fracture is a first hydraulic fracture that emanates from a first wellbore formed in the subterranean formation, and the control volume includes a second hydraulic fracture that emanates from a second wellbore formed in the subterranean formation that is different than the first wellbore.

In another aspect combinable with any one of the previous aspects, the at least one control point includes a plurality of control points representative of at least one of a displacement, a stress tensor, a strain tensor, or a traction vector on a boundary of the second hydraulic fracture.

In another aspect combinable with any one of the previous aspects, the at least one dimension of the hydraulic fracture includes at least one of a half-length of the first hydraulic fracture, a length of the first hydraulic fracture, a half-height of the first hydraulic fracture, or a height of the first hydraulic fracture.

In another aspect combinable with any one of the previous aspects, the at least one dimension of the control volume includes at least one of a half-length of the second hydraulic fracture, a length of the second hydraulic fracture, a half-height of the second hydraulic fracture, or a height of the second hydraulic fracture.

In another aspect combinable with any one of the previous aspects, the hydraulic fracture emanates from a first wellbore formed in the subterranean formation, and the control volume includes a sealed section of a second wellbore formed in the subterranean formation that is different than the first wellbore.

In another aspect combinable with any one of the previous aspects, the at least one control point includes at least one displacement representative of at least one of a displacement, a stress tensor, a strain tensor, or a traction vector on a boundary of the sealed section.

In another aspect combinable with any one of the previous aspects, the at least one dimension of the hydraulic fracture includes at least one of a half-length of the hydraulic fracture, a length of the hydraulic fracture, a half-height of the hydraulic fracture, or a height of the hydraulic fracture.

In another aspect combinable with any one of the previous aspects, the analytical solution includes uᵢ(x)=f(Dim_{cv},Dim_{treatfrac},vec), where uᵢ(x) is the displacement field that includes the at least one control point, and is a function of one or more dimensions of the control volume (Dim_{cv}), one or more dimensions of the treatment fracture (Dim_{treatfrac}), and a vector between the control volume and the treatment fracture (vec).

In another aspect combinable with any one of the previous aspects, the analytical solution further includes uᵢ(x)=f(Dim_{cv}, Dim_{treatfrac}, vec, rot, geo), where uᵢ(x) is the displacement field that includes the at least one control point, and is a function of one or more dimensions of the control volume (Dim_{N}), one or more dimensions of the treatment fracture (Dim_{treatfrac}), a vector between the control volume and the treatment fracture (vec), a rotation of the control volume relative to the treatment fracture (rot), and one or more geologic properties of the subterranean formation (geo).

In another aspect combinable with any one of the previous aspects, the analytical solution includes a modified Eshelby solution.

In another aspect combinable with any one of the previous aspects, the modified Eshelby solution includes one or more equations that determines the at least one control point based at least in part on a plurality of parameters that are associated with the control volume and the hydraulic fracture.

In another aspect combinable with any one of the previous aspects, the plurality of parameters include at least two dimensions of the control volume, at least two dimensions of the hydraulic fracture, and at least three dimensions that represent a vector between the control volume and the hydraulic fracture.

In another aspect combinable with any one of the previous aspects, the plurality of parameters further include at least three dimensions that represent an axis of rotation between the control volume and the hydraulic fracture and an angle of rotation about the axis of rotation.

In another aspect combinable with any one of the previous aspects, the plurality of parameters further include one or more geologic characteristics of the subterranean formation.

In another aspect combinable with any one of the previous aspects, at least one of the equations is

$${u}_{i} ( x ) = \frac{1}{8 π ( 1 - v )} ( {ψ}_{, jli} {ϵ}_{jl}^{*} - 2 v {ϵ}_{m m}^{*} ϕ {,}_{i} - 4 ( 1 - v ) {ϵ}_{il}^{*} ϕ {,}_{i} ) ,$$

where uᵢ(x) represents the displacement field that includes the at least one control point, ∈* is the eigenstrain, and ν is Poisson's ratio. In this equation, ψ and Φ are volume integrals that result from applying a divergence theorem to a specialization of a generalized stress-strain equation for a body force applied on a surface at a point, r′, on a point at an offset displacement, r.

In another aspect combinable with any one of the previous aspects, determining, with a numerical solution executed by the one or more hardware processors, a fluid pressure change of the control volume based on the change to the at least one control point, includes calculating, with the numerical solution executed by the one or more hardware processors, a pressure transfer function on the control volume based on the fluid pressure change on the control volume.

In another aspect combinable with any one of the previous aspects, the pressure transfer function includes Rₛᵢₘ^{l}=g^{l}({x̅^{m},x̅^{t}}^{l})=g^{l}({xᵢ^{m},xᵢ^{t}}^{l})=g^{l}({Dᵢⱼyⱼ^{m},Dᵢⱼyⱼ^{t}}^{l}), where Rₛᵢₘ^{l} a modeled pressure of the control volume, g^{l} is the pressure transfer function, x represents a vector that represents degrees of freedom of the control volume (with m superscript) and the hydraulic fracture (with t superscript).

In another aspect combinable with any one of the previous aspects, determining, with the solver executed by the one or more hardware processors, at least one dimension of at least one of the control volume or the hydraulic fracture based at least in part on the determined fluid pressure change of the control volume, includes performing, with the solver, a global analysis to determine the at least one dimension of the control volume; and performing, with the solver, a local analysis to determine the at least one dimension of the hydraulic fracture.

In another aspect combinable with any one of the previous aspects, performing the global analysis includes performing, with the solver, a single- or multi-objective, non-linear constrained optimization analysis to minimize at least one objective function associated with at least one fluid pressure measured by a pressure sensor in fluid communication with the control volume; and based on minimizing the at least one objective function, determining, with the solver, the at least one dimension of the control volume.

In another aspect combinable with any one of the previous aspects, the at least one objective function includes a first objective function, and minimizing the first objective function includes minimizing a difference between the at least one fluid pressure and the determined fluid pressure change of the control volume.

Another aspect combinable with any one of the previous aspects further includes assessing, with the solver, a shift penalty to the first objective function.

Another aspect combinable with any one of the previous aspects further includes minimizing, with the solver, a second objective function associated with an area of the control volume or the hydraulic fracture.

In another aspect combinable with any one of the previous aspects, minimizing the second objective function includes at least one of minimizing a difference between the area of the control volume and an average area of a group of control volumes that includes the control volume; or minimizing a difference between the area of the hydraulic fracture and an average area of a group of hydraulic fractures in a hydraulic fracturing stage group that includes the hydraulic fracture.

Another aspect combinable with any one of the previous aspects further includes applying, with the solver, a constraint to the single- or multi-objective, non-linear constrained optimization analysis associated with at least one of a center of the control volume or a center of the hydraulic fracture.

Another aspect combinable with any one of the previous aspects further includes iterating the steps until an error for at least one of the first or second objective functions is less than a specified value; and a change in the determined at least one dimension for the control volume or the hydraulic fracture from a previous iteration to a current iteration is less than the specified value.

Other general implementations according to the present disclosure include computing systems and non-transitory, computer readable media. For example, another general implementation includes a distributed computing system that includes one or more memory modules; and one or more hardware processors communicably coupled to the one or more memory modules and configured to execute instructions stored in the one or more memory modules to perform operations including the steps of any one of the computer-implemented methods described herein.

The details of one or more implementations of the subject matter described in this disclosure are set forth in the accompanying drawings and the description below. Other features, aspects, and advantages of the subject matter will become apparent from the description, the drawings, and the claims.

### BRIEF DESCRIPTION OF DRAWINGS

FIGS. 1A-1C are schematic illustrations of an example implementation of a hydraulic fracturing modeling system within a hydraulic fracturing system.

FIG. 2 is a schematic diagram of a structured data processing system that implements the hydraulic fracturing modeling system.

FIG. 3 is a flowchart that describes an example method for determining features of a hydraulic fracture with a hydraulic fracturing modeling system.

### DETAILED DESCRIPTION

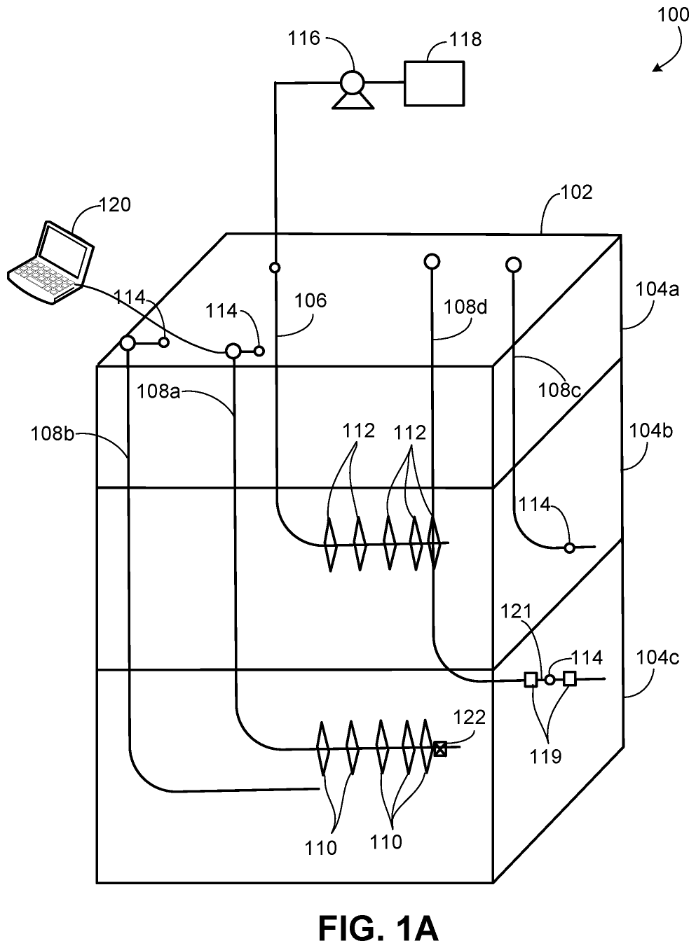

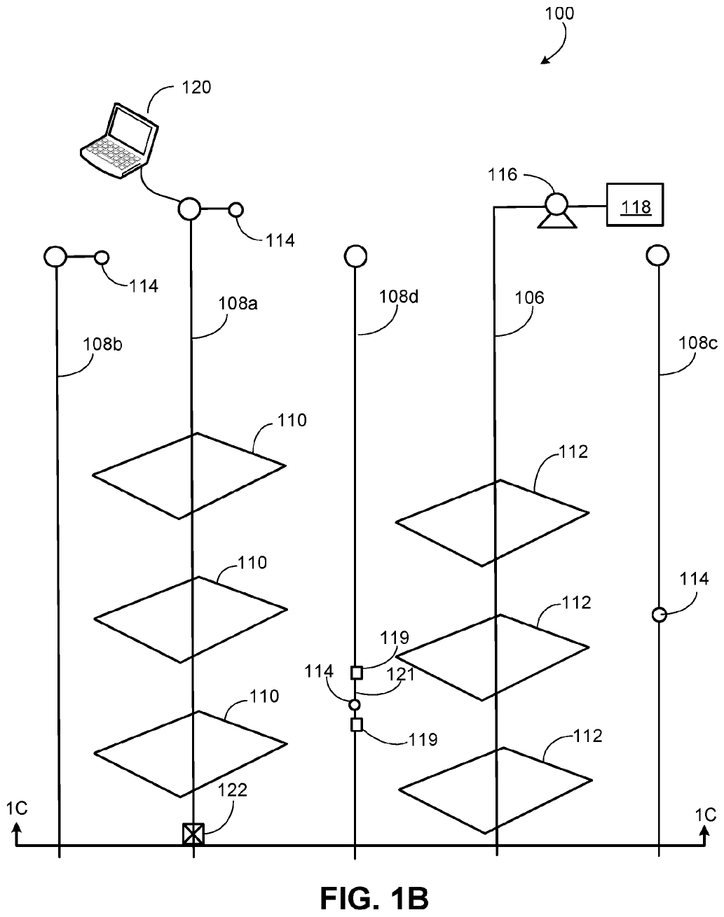

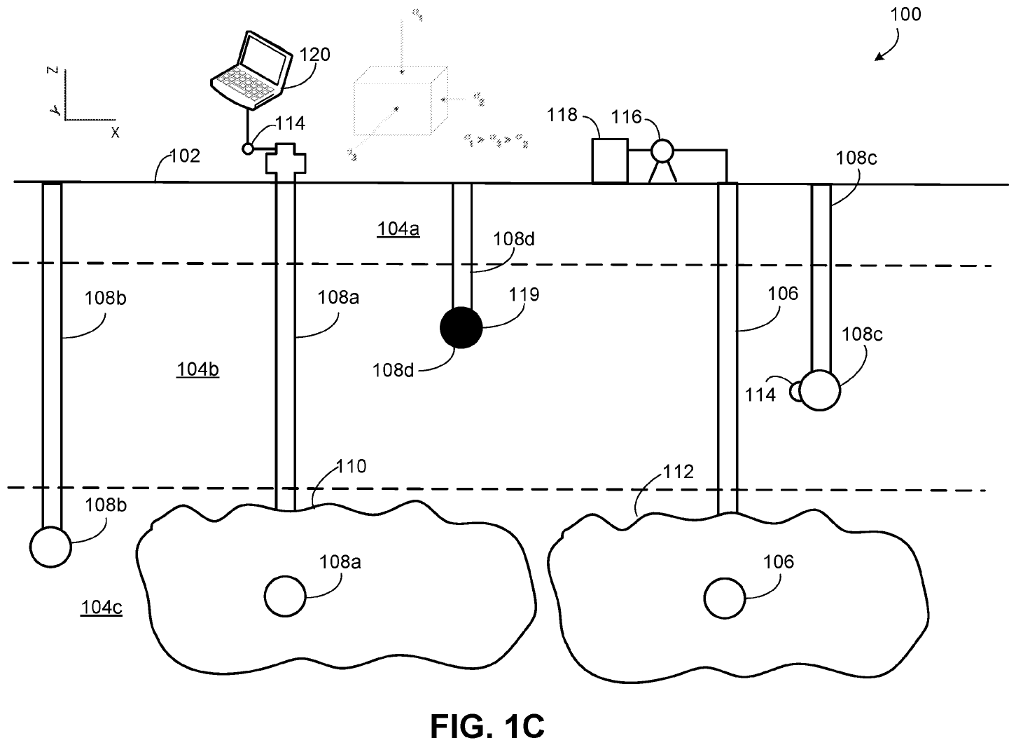

FIGS. 1A-1C are schematic illustrations of an example implementation of a hydraulic fracturing modeling system 120 (a structured data processing system) within a hydraulic fracturing system 100. As shown, system 100 includes one or more monitor wellbores (labeled 108a-108d in this example) that are formed from a terranean surface 102 to one or more subterranean zones 104a-104c located below the terranean surface 102. In this example, one, some, or all of the monitor wellbores 108a-108d may include a plug 122 or other fluid barrier positioned in the particular wellbore 108a-108d, and a pressure sensor 114 (shown fluidly coupled to each monitor wellbore 108a-108d). In this example, the pressure sensor 114 is located at or near a wellhead on one or more of the monitor wellbores 108a-108d, but in alternate implementations, the pressure sensor 114 may be positioned within or about (e.g., inside a casing or mounted externally to a casing) one or more of the particular monitor wellbores 108a-108d below the terranean surface 102. Generally, according to the present disclosure, one or more of the monitor wellbores 108a-108d may be used to measure pressure variations in a fluid contained in the particular wellbore 108a-108d and, in some examples, one or more hydraulic fractures 110 formed from a particular monitor wellbore 108 (in this example, wellbores 108a and 108d) that are induced by a hydraulic fracturing fluid pumped into a treatment wellbore 106 to form one or more hydraulic fractures 112 formed from the treatment wellbore 106. Such induced pressure variations, as explained more fully below, may be used to determine information regarding the hydraulic fractures 110, hydraulic fractures 112, or even (all or a portion of) the wellbores 108a-108d.

Each monitor wellbore 108a-108d shown in FIGS. 1A-1C includes vertical and horizontal sections, as well as a radiused section that connects the vertical and horizontal portions. Generally, and in alternative implementations, each wellbore 108a-108d can include horizontal, vertical (e.g., only vertical), slant, curved, and other types of wellbore geometries and orientations. One or more wellbores 108a-108d may include a casing (not shown) that is cemented or otherwise secured to the wellbore wall to define a borehole in the inner volume of the casing. In alternative implementations, one or more wellbore 108a-108d can be uncased or include uncased sections.

Perforations (not specifically labeled on the wellbores) can be formed in the casing to allow fracturing fluids and/or other materials to flow into the wellbores, such as wellbores 108a and 106. Perforations can be formed using shape charges, a perforating gun, and/or other tools. Wellbores 108b, 108c, and 108d, in this example, however, may include no perforations or an insignificant number of perforations that does not allow significant fluid coupling of the wellbores 108b, 108c, and 108d to the subterranean formation. As another example of a “limited entry process,” a “sliding sleeve” process may be used in lieu of a perforation process in order to gain entry into a subterranean formation from a wellbore.

Although illustrated as generally vertical portions and generally horizontal portions, such parts of the wellbores 108a-108d may deviate from exactly vertical and exactly horizontal (e.g., relative to the terranean surface 102) depending on the formation techniques of the particular wellbore 108a-108d, type of rock formation in the subterranean formations 104a-104c, and other factors. Generally, the present disclosure contemplates all conventional and novel techniques for forming the wellbores 108a-108d from the surface 102 into the subterranean formations 104a-104c.

In this example, wellbore 108a includes hydraulic fractures 110 emanating therefrom. Thus, wellbore 108a may be fluidly coupled to the particular subterranean formation in which it is formed (formation 104c) through the fractures 110. In this example, the pressure sensor 114 may be positioned at the surface 102 (e.g., in a wellhead of wellbore 108a).

In this example, wellbore 108b, in this example, includes no hydraulic fractures and no perforations. Thus, in this example, all or a substantial portion of the wellbore 108b is considered to be fluidly sealed to (or decoupled from) the subterranean formation 104c (i.e., a sealed wellbore, such as a drilled, uncompleted (“DUC”) wellbore). Whether cased or uncased, in this example, the wellbore 108b is a sealed wellbore with a pressure sensor 114 mounted at the surface 102 (e.g., in the wellhead of the wellbore 108b) or within the wellbore 108b (i.e., in fluid contact with the fluid in the wellbore 108b).

In this example, wellbore 108c may also be a sealed or substantially sealed wellbore, e.g., with no hydraulic fractures emanating therefrom. Further, wellbore 108c may have no or an insignificant number of perforations. In this example, the pressure sensor 114 is a casing mounted pressure sensor, positioned, e.g., at a horizontal portion of the wellbore 108c. In this example, the pressure sensor 114 of wellbore 108c is mounted on an exterior of the casing or otherwise positioned so as to be in direct fluid communication with fluids in the subterranean formation 104b.

In this example, wellbore 108d may also be a sealed or substantially sealed wellbore, e.g., with no hydraulic fractures emanating therefrom. Further, wellbore 108d may have no or an insignificant number of perforations. Wellbore 108d, as shown, may include two seals 119 (e.g., packers, bridge plugs, or otherwise) mounted in a portion of the wellbore 108d to define a sealed section 121 of the wellbore 108d. The sealed section 121 is fluidly decoupled from the remaining portions of the wellbore 108d (i.e., uphole of the uphole positioned seal 119 and downhole of the downhole positioned seal 119). In this example, the sealed section 121 is also fluidly decoupled from the subterranean formation 104b. In this example, the sealed section 121 may be much smaller (e.g., in an axial or length dimension) as compared to the entire axial dimension or length of the wellbore 108d. The pressure sensor 114, in this example, is mounted within the sealed section 121 of the wellbore 108d (i.e., in fluid contact with fluid within the sealed section 121).

System 100 in FIGS. 1A-1C, therefore, illustrates several different monitor wellbores. Although a single monitor wellbore is shown for each of the example wellbores 108a-108d, the system 100 may include more or fewer of each of these wellbores 108a-108d. For example, in some aspects, the system 100 may include many monitor wellbores 108a but not any of wellbores 108b, 108c, or 108d. As another example, the system 100 may include a single or multiple monitor wellbores 108d only (along with one or many treatment wellbores 106). Thus, the present disclosure contemplates all variety of combinations of monitor and treatment wellbores within the system 100.

The treatment wellbore 106 shown in FIGS. 1A-1C includes vertical and horizontal sections, as well as a radiused section that connects the vertical and horizontal portions. Generally, and in alternative implementations, the wellbore 106 can include horizontal, vertical (e.g., only vertical), slant, curved, and other types of wellbore geometries and orientations. The treatment wellbore 106 may include a casing (not shown) that is cemented or otherwise secured to the wellbore wall to define a borehole in the inner volume of the casing. In alternative implementations, the wellbore 106 can be uncased or include uncased sections. Perforations (not specifically labeled) can be formed in the casing to allow fracturing fluids and/or other materials to flow into the wellbore 106. Perforations can be formed using shape charges, a perforating gun, and/or other tools. Although illustrated as generally vertical portions and generally horizontal portions, such parts of the wellbore 106 may deviate from exactly vertical and exactly horizontal (e.g., relative to the terranean surface 102) depending on the formation techniques of the wellbore 106, type of rock formation in the subterranean formation 104b, and other factors. Generally, the present disclosure contemplates all conventional and novel techniques for forming the wellbore 106 from the surface 102 into the subterranean formation 104b. Generally, according to the present disclosure, the treatment wellbore 106 is used to form one or more hydraulic fractures 112 that can produce or enhance production of hydrocarbons or other fluids in the subterranean zone 104b (and other formations). A hydraulic fracturing fluid used to form such fractures 112, during formation of the fractures 112, may induce pressure variations in a fluid contained in one or more of the monitor wellbores 108a-108d, which may be used to determine one or more dimensions and other information regarding the hydraulic fractures 112, the hydraulic fractures 110, and even the wellbores 108a-108d.

Although four monitor wellbores 108a-18d and a single treatment wellbore 106 are shown in FIGS. 1A-1C, the present disclosure contemplates that the system 100 may include more or fewer monitor wellbores and more treatment wellbores. In some aspects, monitor wellbores that include hydraulic fractures (i.e., 108a) may also be considered (e.g., at some point in time) as “treatment wellbores,” while a treatment wellbore may also be considered, at some point in time, a monitor wellbore. Monitor wellbores 108b and 108c, in some aspects, may only be considered as “monitor wellbores.”

For example, in some aspects, there may be multiple (e.g., 10 or more) wellbores formed into the subterranean zones 104a-104c, with a single wellbore assigned to be the monitor wellbore and the remaining wellbores assigned to be treatment wellbores. Alternatively, there may be multiple monitor wellbore and multiple treatment wellbores within a set of wellbores formed into the subterranean zone. Further, in some aspects, one or more wellbores in a set of wellbores formed into the subterranean zones 104a-104c may be initially designated as monitor wellbores while one or more other wellbores may be designated as treatment wellbores. Such initial designations, according to the present disclosure, may be adjusted over time such that wellbores initially designated monitor wellbores may be re-designated as treatment wellbores while wellbores initially designated treatment wellbores may be re-designated as monitor wellbores.

The example hydraulic fracturing system 100 includes a hydraulic fracturing liquid circulation system 118 (i.e., a frac spread) that is fluidly coupled to the treatment wellbore 106. In some aspects, the hydraulic fracturing liquid circulation system 118, which includes one or more pumps 116, is fluidly coupled to the subterranean formation 104 (which could include a single formation, multiple formations or portions of a formation) through a working string (not shown). Generally, the hydraulic fracturing liquid circulation system 118 can be deployed in any suitable environment, for example, via skid equipment, a marine vessel, sub-sea deployed equipment, or other types of equipment and include hoses, tubes, fluid tanks or reservoirs, pumps, valves, and/or other suitable structures and equipment arranged to circulate a hydraulic fracturing liquid through the treatment wellbore 106 and into the subterranean formations 104a-104c to generate the one or more fractures 112. The working string is positioned to communicate the hydraulic fracturing liquid into the treatment wellbore 106 and can include coiled tubing, sectioned pipe, and/or other structures that communicate fluid through the wellbore 106. The working string can also include flow control devices, bypass valves, ports, and or other tools or well devices that control the flow of fracturing fluid from the interior of the working string into the subterranean formations 104a-104c.

Although labeled as a terranean surface 102, this surface may be any appropriate surface on Earth (or other planet) from which drilling and completion equipment may be staged to recover hydrocarbons from a subterranean zone. For example, in some aspects, the surface 102 may represent a body of water, such as a sea, gulf, ocean, lake, or otherwise. In some aspects, all are part of a drilling and completion system, including hydraulic fracturing system 100, may be staged on the body of water or on a floor of the body of water (e.g., ocean or gulf floor). Thus, references to terranean surface 102 includes reference to bodies of water, terranean surfaces under bodies of water, as well as land locations.

Subterranean formations 104a-104c may include one or more rock or geologic formations that bear hydrocarbons (e.g., oil, gas) or other fluids (e.g., water) to be produced to the terranean surface 102. For example, the rock or geologic formations can be shale, sandstone, or other type of rock, typically, that may be hydraulically fractured to produce or enhance production of such hydrocarbons or other fluids. In some aspects, one or more of the subterranean formations 104a-104c comprise different rock formations (e.g., shales, sandstones, or otherwise). In some aspects, one or more of the subterranean formations 104a-104c comprise similar rock formations (e.g., shales, sandstones, or otherwise) but in distinct layers represented by the formations 104a-104c (e.g., upper layer, lower layer).

As shown specifically in FIG. 1C, the monitor fractures 110 emanating from the monitor wellbore 108a and the treatment fractures 112 emanating from the treatment wellbore 106 may extend past each other in the plane normal to (perpendicular to) the direction of minimum principal stress (σ₂) when formed. As shown in this example, wellbores are typically drilled in a direction that is as close as possible to the direction of minimum principle stress, such that hydraulic fractures propagate away from the wellbore and not along its trajectory. As shown, when projected to a two dimensional space normal to the direction of minimum principal stress (e.g. the σ₁-σ₃ plane) such fractures overlap in the plane, though they may be separated by significant distance in the direction of σ₂. Further, in some aspects, monitor fractures 110 and treatment fractures 112 (as well as monitor wellbores and treatment wellbores) may be rotated relative to each other as the relationship between σ₁, σ₂, and σ₃ changes along a wellbore. As shown in this figure, a set of rock stress axes are illustrated, with the overburden stress, σ₁, in the same direction as the z-axis. A minimum principal stress, σ₂, and a maximum principal stress, σ₃, are offset 90° from each other. The induced stress field about a newly formed hydraulic fracture is highly non-linear, and while general statements may be made about the magnitude of this induced stress field being related to proximity to the hydraulic fracture—no simple relationship can be assumed relating it to proximity in the direction of minimum principal stress, nor to “overlap” in the plane normal to the direction of minimum principal stress.

FIG. 1C illustrates an example implementation in which the monitor and treatment wellbores 108a-108d and 106, respectively, are formed in a “wine-rack” configuration. In some aspects, implementations of the present disclosure that determine one or more dimensions of the illustrated control volumes, as well as illustrated treatment fractures, may more accurately determine such dimensions in wellbores in a wine-rack formation as compared to previous or conventional solutions.

In some aspects, data about the location of such fractures 110 and 112 and their respective wellbores 108a-108d and 106, such as locations of the wellbores, distances between the wellbores (e.g., in three dimensions) depth of horizontal portions of the wellbores, and locations of the hydraulic fractures initiated from the wellbores (e.g., based on perforation locations formed in the wellbores), among other information. In some aspects, such information (along with the monitored, induced pressure variations in a fluid in the one or more monitor wellbores) may be used to help determine one or more dimensions (e.g., fracture length, fracture half-length, fracture height, fracture area) of the hydraulic fractures 112 and hydraulic fractures 110.

In the present disclosure, one or more features illustrated in FIGS. 1A-1C may be represented or defined as a control volume for the purpose of determining characteristics about that feature (and others) according to the present disclosure. For example, in some aspects, the wellbore 108b (e.g., the sealed wellbore) may be represented or defined as a control volume. Such a control volume, for instance, may be approximated as a cylinder in shape.

As another example, wellbore 108c may be represented or defined as a control volume (but with the pressure sensor 114 positioned in fluid communication with the subterranean formation 104b). Such a control volume, for instance, may also be approximated as cylinder.

As another example, a particular hydraulic fracture 110 that emanates from monitor wellbore 108a may be represented or defined as a control volume. Such a control volume, for instance, may be approximated as, e.g., an ellipsoid in shape. More generally, however, the control volume for the hydraulic fracture 110 may be approximated as a three-dimensional volume in which two principle dimensions (fracture width and fracture height) are of the same or similar magnitude value, and a third principle dimension (fracture aperture) has a magnitude value significantly smaller (e.g., two or more orders of magnitude) than the two principle dimensions.

As another example, the sealed section 121 of wellbore 108d may be represented or defined as a control volume. Such a control volume, since the sealed section 121 can be estimated to be much smaller than the total length and/or volume of the wellbore 108d, may be approximated as a point in shape.

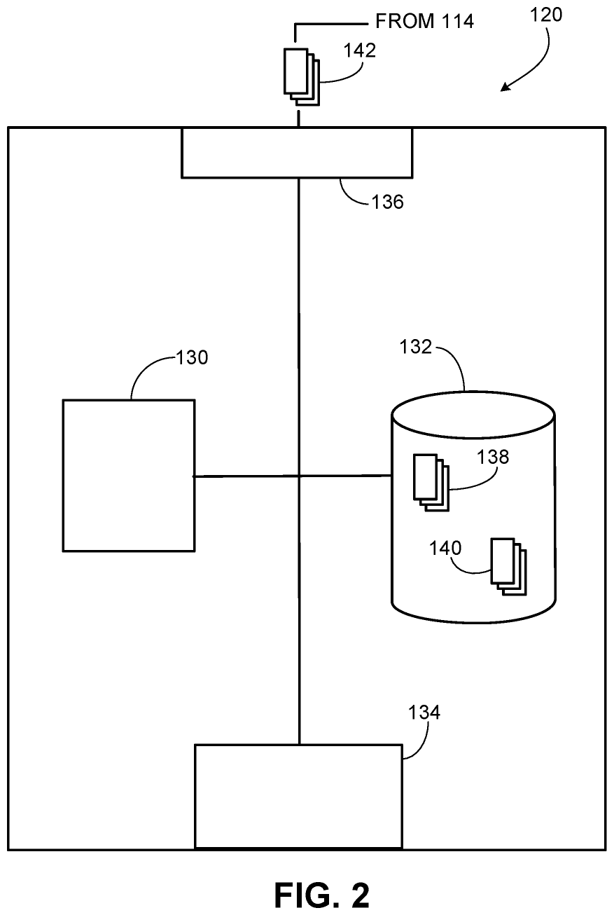

FIG. 2 is a schematic diagram of a computing system that implements the hydraulic fracturing modeling system 120 (structured data processing system) shown in FIGS. 1A-1C. Although illustrated as connected to the wellbore 108a only, generally, the hydraulic fracturing modeling system 120 is capable of receiving or obtaining data from or related to any of the monitor wellbores 108a-108d (and pressure sensors 114 associated with each of these wellbores). Generally, the hydraulic fracturing modeling system 120 includes a processor-based control system operable to implement one or more operations described in the present disclosure. As shown in FIG. 2, pressure signal values 142 may be received at the hydraulic fracturing modeling system 120 from one or more pressure sensors 114 that is fluidly coupled to or in one or more of the monitor wellbores 108a-108d. The pressure signal values 142, in some aspects, may represent pressure variations in a fluid that is enclosed or contained in one or more of the monitor wellbores 108a-108d (and/or the hydraulic fractures 110 that are induced by a hydraulic fracturing fluid being used to form hydraulic fractures 112 from the treatment wellbore 106).

The hydraulic fracturing modeling system 120 may be any computing device operable to receive, transmit, process, and store any appropriate data associated with operations described in the present disclosure. The illustrated hydraulic fracturing modeling system 120 includes hydraulic fracturing modeling application 130 (also called a “solver” in some aspects). The application 130 is any type of application that allows the hydraulic fracturing modeling system 120 to request and view content on the hydraulic fracturing modeling system 120. In some implementations, the application 130 can be and/or include a web browser. In some implementations, the application 130 can use parameters, metadata, and other information received at launch to access a particular set of data associated with the hydraulic fracturing modeling system 120. Further, although illustrated as a single application 130, the application 130 may be implemented as multiple applications in the hydraulic fracturing modeling system 120.

The illustrated hydraulic fracturing modeling system 120 further includes an interface 136, a processor 134, and a memory 132. The interface 136 is used by the hydraulic fracturing modeling system 120 for communicating with other systems in a distributed environment—including, for example, the pressure sensor 114—that may be connected to a network. Generally, the interface 136 comprises logic encoded in software and/or hardware in a suitable combination and operable to communicate with, for instance, the pressure sensor(s) 114, a network, and/or other computing devices. Such systems are often referred to in practice as data “historians.” More specifically, the interface 136 may comprise software supporting one or more communication protocols associated with communications such that a network or interface's hardware is operable to communicate physical signals within and outside of the hydraulic fracturing modeling system 120.

Regardless of the particular implementation, “software” may include computer-readable instructions, firmware, wired or programmed hardware, or any combination thereof on a tangible medium (transitory or non-transitory, as appropriate) operable when executed to perform at least the processes and operations described herein. Indeed, each software component may be fully or partially written or described in any appropriate computer language including C, C++, Java, Visual Basic, ABAP, assembler, Perl, Python, .NET, Matlab, any suitable version of 4GL, as well as others. While portions of the software illustrated in FIG. 2 are shown as individual modules that implement the various features and functionality through various objects, methods, or other processes, the software may instead include a number of sub-modules, third party services, components, libraries, and such, as appropriate. Conversely, the features and functionality of various components can be combined into single components as appropriate.

The processor 134 executes instructions and manipulates data to perform the operations of the hydraulic fracturing modeling system 120. The processor 134 may be a central processing unit (CPU), a blade, an application specific integrated circuit (ASIC), a field-programmable gate array (FPGA), graphics processing unit (GPU), or another suitable component. Generally, the processor 134 executes instructions and manipulates data to perform the operations of the hydraulic fracturing modeling system 120.

Although illustrated as a single memory 132 in FIG. 2, two or more memories may be used according to particular needs, desires, or particular implementations of the hydraulic fracturing modeling system 120. In some implementations, the memory 132 is an in-memory database. While memory 132 is illustrated as an integral component of the hydraulic fracturing modeling system 120, in some implementations, the memory 132 can be external to the hydraulic fracturing modeling system 120. The memory 132 may include any memory or database module and may take the form of volatile or non-volatile memory including, without limitation, magnetic media, optical media, random access memory (RAM), read-only memory (ROM), removable media, or any other suitable local or remote memory component. The memory 132 may store various objects or data, including classes, frameworks, applications, backup data, business objects, jobs, web pages, web page templates, database tables, repositories storing business and/or dynamic information, and any other appropriate information including any parameters, variables, algorithms, instructions, rules, constraints, or references thereto associated with the purposes of the hydraulic fracturing modeling system 120.

The illustrated hydraulic fracturing modeling system 120 is intended to encompass any computing device such as a desktop computer, laptop/notebook computer, wireless data port, smart phone, smart watch, wearable computing device, personal data assistant (PDA), tablet computing device, one or more processors within these devices, or any other suitable processing device. For example, the hydraulic fracturing modeling system 120 may comprise a computer that includes an input device, such as a keypad, touch screen, or other device that can accept user information, and an output device that conveys information associated with the operation of the hydraulic fracturing modeling system 120 itself, including digital data, visual information, or a GUI.

As illustrated in FIG. 2, the memory 132 stores structured or unstructured (e.g. raw text files with no predefined taxonomy) data, including one or more poromechanical models 138. In some aspects, a poromechanical model 138 may be in the form of a pressure transfer function (or functions) that describes poromechanical interactions between, one or more of the hydraulic fractures 112 and one or more of: (1) one or more of the wellbores 108a-108d, (2) one or more of the hydraulic fractures 110, or (3) the sealed section 121 of the wellbore 108d. However, other data structures of the model 138 are contemplated by the present disclosure.

The poromechanical interactions may be identified using pressure signals measured by one or more pressure sensors 114 of a fluid contained in one or more of the monitor wellbores 108a-108d or the hydraulic fractures 110. The poromechanical interactions may also be identified using one or more pressure sensors or other components that measure a pressure of a hydraulic fracturing fluid used to form the hydraulic fractures 112 from the treatment wellbore 106. In certain embodiments, the pressure signals include a pressure versus time curve of the pressure signal. Pressure-induced poromechanic signals may be identified in the pressure versus time curve and the pressure-induced poromechanic signals may be used to assess one or more parameters (e.g., geometry) of the hydraulic fractures 112. In some aspects, a “pressure-induced poromechanic signal” refers to a recordable change in pressure of a first fluid within a control volume. The recordable change in the pressure of the first fluid, in some aspects, is caused by a change in stress field on a solid in a subsurface formation that is due to a second fluid used in a hydraulic stimulation process (e.g., a hydraulic fracturing process) in a treatment wellbore 106 in proximity to (e.g., adjacent) the control volume. In some cases, the second fluid is not in direct fluid communication with the first fluid (i.e., no mass flux change in the first fluid due to the second fluid).

For example, with reference to monitor wellbores 108a and 108d, a pressure-induced poromechanic signal may occur in the pressure sensor 114 attached to the wellhead of the monitor wellbore 108a and/or 108d, where at least one stage of that monitor wellbore 108a has already been hydraulically fractured to create the fractures 110 (assumed, for this example, to be part of a common fracturing stage), when the adjacent treatment wellbore 106 undergoes hydraulic stimulation. A particular hydraulic fracture 112 emanating from the treatment wellbore 106 may grow in proximity to the fracture 110 but these fractures may not intersect and/or overlap. No fluid from the hydraulic fracturing process in the treatment wellbore 106 contacts any fluid in the hydraulic fractures 110 and no measurable pressure change in the fluid in the hydraulic fractures 110 is caused by advective or diffusive mass transport related to the hydraulic fracturing process in the treatment wellbore 106. Thus, the interaction of the fluids in the hydraulic fracture 112 with fluids in the subsurface matrix does not result in a recordable pressure change in the fluids in the fracture 110 that can be measured by the pressure sensor 114. The change in stress on a rock (in the subterranean zone 104) in contact with the fluids in the fracture 112, however, may cause a change in pressure in the fluids in the fracture 110, which can be measured as a pressure-induced poromechanic signal in the pressure sensor 114.

Poromechanic signals may be present in traditional pressure measurements taken in the monitor wellbore 108a while fracturing the treatment wellbore 106. For example, if a newly formed hydraulic fracture 112 overlaps or grows in proximity to a particular hydraulic fracture 110 in fluid communication with the pressure sensor 114 in the monitor wellbore 108a, one or more poromechanic signals may be present. However, poromechanic signals may be smaller in nature than a direct fluid communication signal (e.g., a direct pressure signal induced by direct fluid communication such as a direct fracture hit or fluid connectivity through a high permeability fault). Poromechanic signals may also manifest over a different time scale than direct fluid communication signals. Thus, poromechanic signals are often overlooked, unnoticed, or disregarded as data drift or error in the pressure sensor 114. However, such signals may be used, at least in part, to determine one or more of a fracture length, fracture height, fracture growth curve and other associated fracture dimensions of the hydraulic fractures 112 that emanate from the treatment wellbore 106.

With reference to monitor wellbore 108b, a pressure-induced poromechanic signal may occur in the pressure sensor 114 attached to the wellhead (or in the wellbore) of the monitor wellbore 108b when the adjacent treatment wellbore 106 undergoes hydraulic stimulation. A particular hydraulic fracture 112 emanating from the treatment wellbore 106 may grow in proximity to the wellbore 108b, but these fractures 112 may or may not intersect and/or overlap the wellbore 108b No fluid from the hydraulic fracturing process in the treatment wellbore 106 contacts any fluid in the wellbore 108b (i.e., as a sealed wellbore) and no measurable pressure change in the fluid in the wellbore 108b is caused by advective or diffusive mass transport related to the hydraulic fracturing process in the treatment wellbore 106. Thus, the interaction of the fluids in the hydraulic fracture 112 with fluids in the subsurface matrix does not result in a recordable pressure change in the fluids in the monitor wellbore 108b that can be measured by the pressure sensor 114. The change in stress on a rock (in the subterranean zone 104) in contact with the fluids in the fracture 112, however, may cause a change in pressure in the fluids in the wellbore 108b, which can be measured as a pressure-induced poromechanic signal in the pressure sensor 114 fluidly coupled to the wellbore 108b.

With reference to monitor wellbore 108c, a pressure-induced poromechanic signal may occur in the pressure sensor 114, e.g., attached to a casing of the monitor wellbore 108c when the adjacent treatment wellbore 106 undergoes hydraulic stimulation. A particular hydraulic fracture 112 emanating from the treatment wellbore 106 may grow in proximity to the wellbore 108c, but these fractures 112 may or may not intersect and/or overlap the wellbore 108c. No fluid from the hydraulic fracturing process in the treatment wellbore 106 contacts any fluid in the wellbore 108c and no measurable pressure change in the fluid in the wellbore 108c is caused by advective or diffusive mass transport related to the hydraulic fracturing process in the treatment wellbore 106. Thus, the interaction of the fluids in the hydraulic fracture 112 with fluids in the subsurface matrix does not result in a recordable pressure change in the fluids in the monitor wellbore 108c that can be measured by the pressure sensor 114. The change in stress on a rock (in the subterranean zone 104) in contact with the fluids in the fracture 112, however, may cause a change in pressure in the fluids in the wellbore 108c, which can be measured as a pressure-induced poromechanic signal in the pressure sensor 114.

With reference to monitor wellbore 108d, a pressure-induced poromechanic signal may occur in the pressure sensor 114 mounted in fluid communication with the sealed section 121 of the monitor wellbore 108d when the adjacent treatment wellbore 106 undergoes hydraulic stimulation. A particular hydraulic fracture 112 emanating from the treatment wellbore 106 may grow in proximity to the wellbore 108d, but these fractures 112 may not intersect and/or overlap the sealed section 121 of the wellbore 108d. No fluid from the hydraulic fracturing process in the treatment wellbore 106 contacts any fluid in the sealed section 121 of the wellbore 108d and no measureable pressure change in the fluid in the wellbore 108d is caused by advective or diffusive mass transport related to the hydraulic fracturing process in the treatment wellbore 106. Thus, the interaction of the fluids in the hydraulic fracture 112 with fluids in the subsurface matrix does not result in a recordable pressure change in the fluids in the monitor wellbore 108c that can be measured by the pressure sensor 114. The change in stress on a rock (in the subterranean zone 104) in contact with the fluids in the fracture 112, however, may cause a change in pressure in the fluid in the sealed section 121 of the wellbore 108d, which can be measured as a pressure-induced poromechanic signal in the pressure sensor 114 (i.e., mounted in fluid communication with the sealed section 121).

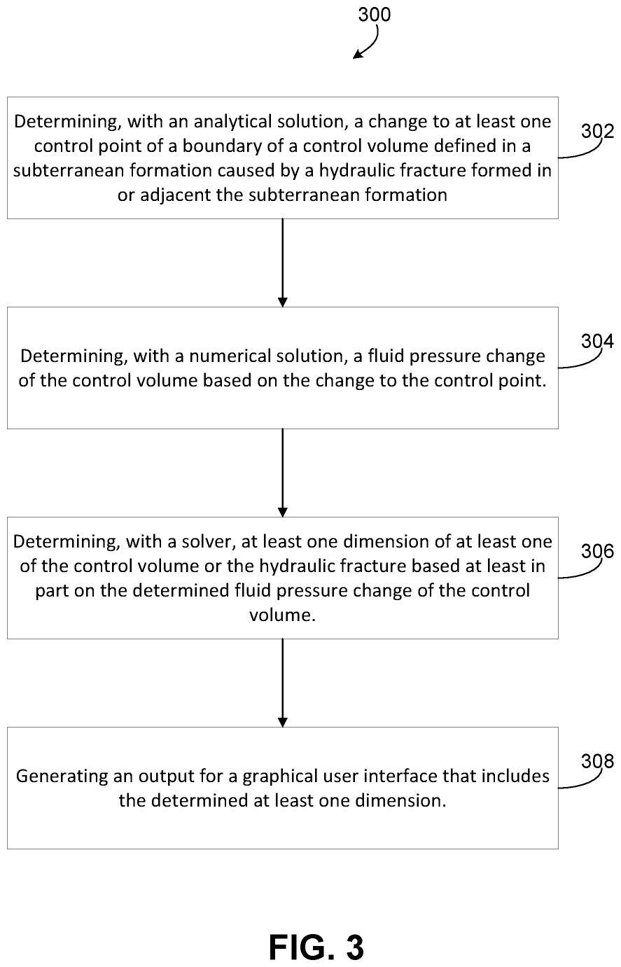

FIG. 3 is a flowchart that describes an example method 300 for determining features of a hydraulic fracture with a hydraulic fracturing modeling system, such as hydraulic fracturing modeling system 120 shown in FIGS. 1A-1C and 2. Method 300 may begin at step 302, which includes determining, with an analytical solution, a change to at least one control point of a boundary of a control volume defined in a subterranean formation caused by a hydraulic fracture formed in or adjacent the subterranean formation. The analytical solution, in some aspects, may be a closed-form solution to a boundary value problem in terms of a mathematical framework that calculates the exact solution and involves no spatial or time discretization. In some aspects, as part of the method 300, the analytical solution may provide a solution for a first, or primary boundary value problem.

For example, an analytical solution executed by the hydraulic fracture modeling system 120 may, generally, derive properties at multiple control points for a control volume. Each control point, in some aspects, may be a point in a spatial domain (i.e., in a subterranean formation) for which an analytical solution is evaluated, and for which the calculated numerical value is introduced to a numerical solution as a boundary condition. The control volume, in some aspects, may be a sub-region of the spatial domain for which conservation of mass and (linear) momentum are evaluated.

In some aspects, the control point may be multiple control points that describe displacements of a boundary of a particular control volume (e.g., wellbore, sealed section, hydraulic fracture) of a monitor wellbore. Thus, changes to the one or more control points describe or define a displacement field that assigns a displacement vector to all points within the spatial domain (i.e., the control volume). A displacement vector, in some aspects, may represent a change in spatial position of a material point (e.g., a control point) with respect to a reference state (e.g., undeformed configuration). Each control point represents an incremental, three-dimensional displacement of a “point” of rock that lies on the boundary of the particular control volume. The displacement of each control point, in some aspects, is caused by the poromechanic interaction of the point due to fracturing of a treatment wellbore that induces a hydraulic fracture that emanates from the treatment wellbore.

In another example, the control point may be multiple control points that describe stress on a boundary of a particular control volume (e.g., wellbore, sealed section, hydraulic fracture) of a monitor wellbore. Thus, changes to the one or more control points describe or define a stress field that assigns a stress tensor to all points within the spatial domain (i.e., the control volume). A stress tensor, in some aspects, may represent a second order spatial tensor representative of “internal” material stresses acting on an infinitesimal small volume that may satisfy local linear and angular equilibriums. In some cases, the stress tensor is governed by constitutive equations that relate the stress tensor to physical quantities, e.g., strain (rate), fluid pressure, etc., and which can be time dependent, history dependent, and non-local. Each control point represents an incremental, three-dimensional stress on a “point” of rock that lies on the boundary of the particular control volume. The stress of each control point, in some aspects, is caused by the poromechanic interaction of the point due to fracturing of a treatment wellbore that induces a hydraulic fracture that emanates from the treatment wellbore.

In another example, the control point may be multiple control points that describe strain on a boundary of a particular control volume (e.g., wellbore, sealed section, hydraulic fracture) of a monitor wellbore. Thus, changes to the one or more control points describe or define a strain field that may be a spatial gradient, or strain tensor, of a displacement field within the spatial domain (i.e., the control volume). A strain tensor, in some aspects, may be the derivative of a displacement field at the control point. Each control point represents an incremental, three-dimensional strain on a “point” of rock that lies on the boundary of the particular control volume. The strain of each control point, in some aspects, is caused by the poromechanic interaction of the point due to fracturing of a treatment wellbore that induces a hydraulic fracture that emanates from the treatment wellbore.

In another example, the control point may be multiple control points that describe traction of a boundary of a particular control volume (e.g., wellbore, sealed section, hydraulic fracture) of a monitor wellbore. Thus, changes to the one or more control points describe or define a traction field that assigns a traction vector to all points on a two-dimensions surface within a spatial domain (i.e., the control volume). A traction vector, in some aspects, may be an internal material force acting on the infinitesimally small two-dimensional surface within the spatial domain. Thus, in some aspects, the traction vector may be the component of the stress tensor that is acting on a surface with a certain orientation. Each control point represents an incremental, three-dimensional traction on a “point” of rock that lies on the boundary of the particular control volume. The traction of each control point, in some aspects, is caused by the poromechanic interaction of the point due to fracturing of a treatment wellbore that induces a hydraulic fracture that emanates from the treatment wellbore.

In some aspects, the analytical solution includes or is based on a modified Eshelby solution. For instance, in some aspects of step 302, the analytical solution includes the determination of a displacement field (i.e., control points) on the boundary of the particular control volume. For a sealed wellbore, the control volume may approximate a cylinder. For a hydraulic fracture, the control volume may approximate an ellipsoid. Thus, for such three dimensional control volumes, the displacement field determined in the analytical solution may include multiple control points. For a sealed section of a wellbore that is sufficiently smaller than the wellbore, itself, the control volume may approximate a point in the subterranean formation; thus the displacement field determined in the analytical solution may be a single control point.

In some aspects of step 302, the displacement field may be determined or written as: uᵢ(x)=f(Dim_{cv}, Dim_{treatfrac}, vec, rot, geo),

where uᵢ(x) is the displacement field (i.e., multiple control points each represented by u(x) as i=0 to i=n). Thus, in this example, the displacement field, generally, is a function of one or more dimensions of the control volume (Dim_{cv}), one or more dimensions of the treatment fracture (Dim_{treatfrac}), a vector between the control volume and the treatment fracture (vec), a rotation of the control volume relative to the treatment fracture (rot), and one or more geologic properties of the subterranean formation (geo). In some aspects, one or more of the parameters provided in this function may not be used or needed, such as, for example, the geo and/or rot terms. Thus, in some aspects, this equation may reduce to:

uᵢ(x)=f(Dim_{cv},Dim_{treatfrac},vec).

A more specific example of an analytical solution for the displacement field is for example:

$${u}_{i} ( x ) = \frac{1}{8 π ( 1 - v )} ( {ψ}_{, jli} {ϵ}_{jl}^{*} - 2 v {ϵ}_{m m}^{*} ϕ {,}_{i} - 4 ( 1 - v ) {ϵ}_{il}^{*} ϕ {,}_{i} ) , ,$$

where uᵢ(x) represents the displacement field (i.e., the one or more control points) of the control volume, ∈* is the eigenstrain, ν is Poisson's ratio, and ψ and Φ are volume integrals that result from applying a divergence theorem to a specialization of a generalized stress-strain equation for a body force applied on a surface at a point, r′, on a point at an offset displacement, r.

For example, an elastic strain field can be described for an ellipsoidal inclusion within an infinite matrix. Both the matrix and the inclusion can be homogeneous and isotropically elastic. An interior strain tensor of the inclusion can be uniform and linear to the eigenstrain tensor by a 4^{th} order tensor (e.g., an Eshelby tensor). Further, the elastic strain field can be described that is external to the inclusion. There can be a linear relation between elastic strain and eigenstrain. However, in the case of the strain field external to the inclusion, the 4th order tensor may not be constant but can be dependent on a distance to a center of the inclusion. The strain formulation can then be modified into a displacement field, uᵢ, description given by

$${u}_{i} ( x ) = \frac{1}{8 π ( 1 - v )} ( {ψ}_{, jli} {ϵ}_{jl}^{*} - 2 v {ϵ}_{m m}^{*} ϕ {,}_{i} - 4 ( 1 - v ) {ϵ}_{il}^{*} ϕ {,}_{i} ) ,$$

where x represents the point at which the displacement field is being evaluated (relative to the inclusion center), ν is the Poisson's ratio, ε* is the (uniform) eigenstrain, and Φ and ψ are both scaler fields that depend on the distance to the inclusion center. In the above equation, the third spatial derivative of ψ and the first spatial derivative of Φ are now used to express the linear relation between the eigenstrain and the displacement field.

Method 300 may continue at step 304, which includes determining, a numerical solution for a secondary (or second) boundary value problem (with the analytical solution being a solution to a first or primary boundary value problem) of the (fluid) pressure change of the control volume. The numerical solution includes a (fluid) pressure change of the control volume that may be determined, for example, by perturbing (e.g., substituting) the control volume's poromechanical properties from reservoir to fracture properties. The numerical solution, in some aspects, may allow for the mechanical equilibrium to be satisfied (restored), thereby providing the value for the change in (fluid) pressure in the control volume. The secondary boundary value problem may be constructed such that the values determined at the control point (or points) serve as boundary condition (or conditions). In some aspects, a numerical solution is distinct from an analytical solution in that the numerical solution may be an approximated solution of the boundary value problem derived from a spatial and/or time discretization; the solution converges to the exact solution upon refinement of the discretization.

For example, once the at least one control point (e.g., displacement field) is determined in step 302, a secondary boundary value problem is constructed such that (at least one) of its boundary conditions is controlled by the displacement field evaluated at the control points. The numerical solution (rather than the analytical solution) is executed to determine the (fluid) pressure change on the control volume based at least in part on the poromechanic interaction of the field due to fracturing of the treatment wellbore that induces the hydraulic fracture that emanates from the treatment wellbore. Generally, step 304 includes calculating a numerical solution to determine a (fluid) pressure change in the control volume, which may be proportional to the net pressure applied in the treatment fracture.

In another aspect of step 304, the secondary boundary value problem (i.e., the numerical solution) may be constructed such that a stress field serves as a boundary condition. The numerical solution may thus determine the (fluid) pressure change of the control volume based on the evaluated stress tensors determined at the control point based on the analytical solution of the first boundary value problem.

In another aspect of step 304, the secondary boundary value problem (i.e., the numerical solution) may be constructed such that a strain field serves as a boundary condition. The numerical solution may thus determine the (fluid) pressure change of the control volume based on the evaluated strain tensors determined at the control point based on the analytical solution of the first boundary value problem.

In another aspect of step 304, the secondary boundary value problem (i.e., the numerical solution) may be constructed such that a traction field serves as a boundary condition. The numerical solution may thus determine the (fluid) pressure change of the control volume based on the evaluated traction vectors determined at the control point based on the analytical solution of the first boundary value problem.

Method 300 may continue at step 306, which includes determining, with a solver, at least one dimension of at least one of the control volume or the hydraulic fracture based at least in part on the determined fluid pressure change of the control volume. For example, the solver (of the hydraulic fracture modeling system 120) may, generally, execute a comparison of the fluid pressure change of the control volume of the monitor wellbore (i.e., the modeled fluid pressure change) with an observed pressure, i.e., as recorded by a pressure sensor in fluid communication with the control volume of the monitor wellbore. For example, in some aspects, modeled dimensions of the control volume may be associated with particular modeled pressures, e.g., in a poromechanical model of the hydraulic fracture modeling system 120. As the modeled fluid pressure change (from step 304) approaches or equals the observed pressure taken by the pressure sensor of the monitor wellbore, the dimension of the control volume is determined. In some aspects, a dimension of the control volume may, in turn, be used to determine or approximates a dimension of the hydraulic fracture of the treatment wellbore.

In some aspects of step 306, a pressure transfer function is executed to determine at least one dimension of at least one of the control volume or the hydraulic fracture based at least in part on the determined fluid pressure change of the control volume (as described in U.S. patent application Ser. No. 15/979,420, incorporated by reference in its entirety herein). For example, the poromechanic model may link parameters or dimensions of the control volume to modeled poromechanical responses (i.e., a modeled fluid pressure change in the control volume). Each simulated response may be a function of a set of control volume dimensions. In some aspects, a pressure transfer function is, e.g., a transfer function that relates an input scalar (e.g., a fluid pressure in a treatment wellbore) to an output scalar (e.g., a fluid pressure in a control volume). In some aspects, a pressure transfer function may be highly non-linear and a function of, e.g., fracture dimensions, relative fracture positions, and orientation.

In some aspects, the pressure transfer function (also called a poromechanical response model function) may be provided as:

Rₛᵢₘ^{l}=g^{l}({x̅^{m},x̅^{t}}^{l})=g^{l}({xᵢ^{m},xᵢ^{t}}^{l})=g^{l}({Dᵢⱼyⱼ^{m},Dᵢⱼyⱼ^{t}}^{l}),

where Rₛᵢₘ^{l} is a modeled pressure of the control volume, g^{l} is the poromechanical response model function, x represents a vector that represents degrees of freedom of the control volume (with m superscript) and the hydraulic fracture (with t superscript).

Using this equation, an objective function can be constructed. The objective function may also include one or more constraints (or constraint functions). The objective function may be represented by f₀(x̅). Constraint functions may be represented by fₘ(x̅) and bounds, bm. A constraint limits where in the solution space a minimum of f₀(x̅) may be found. This may be also referred to as a feasible region, Ω. In some aspects, there are both linear and non-linear constraints which allow the embedding of physical knowledge of solution feasibility into the solution.

An example of a linear constraint, the limitation that a control volume (e.g., a monitor fracture) must intersect a wellbore may be set. For example, a shift of the fracture origin in the plane of the fracture for a simple rectangular fracture (as a control volume) may be constrained so it cannot exceed the fracture half-length if the fracture is to originate along the wellbore.

As another example constraint, a non-linear constraint may be defined by constraining the relationship between relative dimensions of the control volume (e.g., as a fracture, a fracture length and height). As another example constraint, a non-linear constraint may be defined by limiting the area of the control volume according to other, similar control volumes (e.g., limiting a monitor fracture area based on an average of fracture areas of other monitor fractures on the same wellbore or same stage). As another example, constraints may act as secondary objective functions. For example, a solution may be desirable that matches the observed poromechanical responses with minimum control volume asymmetry (e.g., within a specified tolerance).

There are many possible constraints that can be specified, both linear and non-linear. Such constraints may have a significant impact on the resulting solution, and should be chosen carefully to yield a useful solution. For example, as described, techniques for determining control volume dimensions (e.g., geometries) may include nonlinear optimization techniques. Such techniques include algorithms for solving constrained, non-linear optimization problems of continuous variables in standard form, e.g., the Trust-Region family of algorithms (Branch, et al., 1999) (Byrd, et al., 1988); the Sequential Quadratic Programming (SQP) Algorithm (Biggs, 1975) (Han, 1977) (Powell, 1978) (Schittkowski, 1985) (Spellucci, 1998); and the Interior Point Algorithm (Byrd, et al., 2000) (Byrd, et al., 1999) (Waltz, et al., 2006), among others. Also, the SQP and Interior Point Algorithm may be most suitable in practice. For example, the Interior Point Algorithm may be suitable or preferred for computational efficiency reasons.

Step 306 may also include the determination of one or more dimensions of the hydraulic fracture, i.e., the treatment fracture formed from the treatment wellbore. For example, the solver may set the determined dimension (or dimensions) of the control volume on the monitor wellbore and then vary the individual treatment fracture parameters.

Method 300 may continue at step 308, which includes generating an output for a graphical user interface that includes the determined at least one dimension of the control volume, the hydraulic fracture, or both. In some aspects, the output may be generated for multiple control volumes as method 300 is repeated for multiple monitor wellbores or multiple control volumes for a single monitor wellbore.

The features described can be implemented in digital electronic circuitry, or in computer hardware, firmware, software, or in combinations of them. The apparatus can be implemented in a computer program product tangibly embodied in an information carrier, for example, in a machine-readable storage device for execution by a programmable processor; and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

To provide for interaction with a user, the features can be implemented on a computer having a display device such as a CRT (cathode ray tube) or LCD (liquid crystal display) monitor for displaying information to the user and a keyboard and a pointing device such as a mouse or a trackball by which the user can provide input to the computer. Additionally, such activities can be implemented via touchscreen flat-panel displays and other appropriate mechanisms.

The features can be implemented in a control system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include a local area network (“LAN”), a wide area network (“WAN”), peer-to-peer networks (having ad-hoc or static members), grid computing infrastructures, and the Internet.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

A number of implementations have been described. Nevertheless, it will be understood that various modifications may be made without departing from the spirit and scope of the disclosure. For example, example operations, methods, or processes described herein may include more steps or fewer steps than those described. Further, the steps in such example operations, methods, or processes may be performed in different successions than that described or illustrated in the figures. Accordingly, other implementations are within the scope of the following claims.

1-46. (canceled)

47. A distributed computing system, comprising:
one or more memory modules; and
one or more hardware processors communicably coupled to the one or more memory modules and configured to execute instructions stored in the one or more memory modules to perform operations comprising:
determining, with an analytical solution, a change to at least one control point of a boundary of a control volume defined in a subterranean formation, the change to the at least one control point caused by a hydraulic fracture formed in or adjacent the subterranean formation;
determining, with a numerical solution, a fluid pressure change of the control volume based on the change to the at least one control point; and
determining, with a solver, at least one dimension of at least one of the control volume or the hydraulic fracture based at least in part on the determined fluid pressure change of the control volume.

48. The distributed computing system of claim 47, wherein the change to the at least one control point comprises a displacement field.

49. The distributed computing system of claim 48, wherein the operation of determining the fluid pressure change of the control volume based on the change to the at least one control point comprises:
evaluating a displacement vector of the displacement field; and
determining the fluid pressure change of the control volume based on the evaluation of the displacement vector.

50. The distributed computing system of claim 48, wherein the at least one control point defines at least one displacement on the boundary of the control volume.

51. The distributed computing system of claim 50, wherein the at least one control point comprises a plurality of control points that define the displacement field.

52. The distributed computing system of claim 47, wherein the change to the at least one control point comprises a stress field.

53. The distributed computing system of claim 52, wherein the operation of determining the fluid pressure change of the control volume based on the change to the at least one control point comprises:
evaluating a stress tensor of the stress field; and
determining the fluid pressure change of the control volume based on the evaluation of the stress tensor.

54. The distributed computing system of claim 52, wherein the at least one control point defines at least one stress on the boundary of the control volume.

55. The distributed computing system of claim 54, wherein the at least one control point comprises a plurality of control points that define the stress field.

56. The distributed computing system of claim 47, wherein the change to the at least one control point comprises a strain field.

57. The distributed computing system of claim 56, wherein the operation of determining the fluid pressure change of the control volume based on the change to the at least one control point comprises:
evaluating a strain tensor of the strain field; and
determining the fluid pressure change of the control volume based on the evaluation of the strain tensor.

58. The distributed computing system of claim 56, wherein the at least one control point defines at least one strain on the boundary of the control volume.

59. The distributed computing system of claim 58, wherein the at least one control point comprises a plurality of control points that define the strain field.

60. The distributed computing system of claim 47, wherein the change to the at least one control point comprises a traction field.

61. The distributed computing system of claim 60, wherein the operation of determining the fluid pressure change of the control volume based on the change to the at least one control point comprises:
evaluating a traction vector of the traction field; and
determining the fluid pressure change of the control volume based on the evaluation of the traction vector.

62. The distributed computing system of claim 60, wherein the at least one control point defines at least one traction on the boundary of the control volume.

63. The distributed computing system of claim 62, wherein the at least one control point comprises a plurality of control points that define the traction field.

64. The distributed computing system of claim 47, wherein the control volume comprises at least a portion of a wellbore formed from a terranean surface to the subterranean formation, and the wellbore is fluidly sealed from the hydraulic fracture.

65. The distributed computing system of claim 64, wherein the at least one control point comprises a plurality of control points representative of a plurality of displacements on a boundary of the portion of the wellbore.

66. The distributed computing system of claim 64, wherein the wellbore comprises a first wellbore, and the hydraulic fracture formed in or adjacent the subterranean formation emanates from a second wellbore different than the first wellbore.

67. The distributed computing system of claim 64, wherein the at least one dimension of the hydraulic fracture comprises at least one of a half-length of the hydraulic fracture, a length of the hydraulic fracture, a half-height of the hydraulic fracture, or a height of the hydraulic fracture.

68. The distributed computing system of claim 47, wherein the hydraulic fracture is a first hydraulic fracture that emanates from a first wellbore formed in the subterranean formation, and the control volume comprises a second hydraulic fracture that emanates from a second wellbore formed in the subterranean formation that is different than the first wellbore.

69. The distributed computing system of claim 68, wherein the at least one control point comprises a plurality of control points representative of at least one of a displacement, a stress tensor, a strain tensor, or a traction vector on a boundary of the second hydraulic fracture.

70. The distributed computing system of claim 68, wherein the at least one dimension of the hydraulic fracture comprises at least one of a half-length of the first hydraulic fracture, a length of the first hydraulic fracture, a half-height of the first hydraulic fracture, or a height of the first hydraulic fracture.

71. The distributed computing system of claim 68, wherein the at least one dimension of the control volume comprises at least one of a half-length of the second hydraulic fracture, a length of the second hydraulic fracture, a half-height of the second hydraulic fracture, or a height of the second hydraulic fracture.

72. The distributed computing system of claim 47, wherein the hydraulic fracture emanates from a first wellbore formed in the subterranean formation, and the control volume comprises a sealed section of a second wellbore formed in the subterranean formation that is different than the first wellbore.

73. The distributed computing system of claim 72, wherein the at least one control point comprises at least one displacement representative of at least one of a displacement, a stress tensor, a strain tensor, or a traction vector on a boundary of the sealed section.

74. The distributed computing system of claim 72, wherein the at least one dimension of the hydraulic fracture comprises at least one of a half-length of the hydraulic fracture, a length of the hydraulic fracture, a half-height of the hydraulic fracture, or a height of the hydraulic fracture.

75. The distributed computing system of claim 47, wherein the analytical solution comprises uᵢ(x)=f(Dim_{cv},Dim_{treatfrac},vec),
where uᵢ(x) is the displacement field that comprises the at least one control point, and is a function of one or more dimensions of the control volume (Dim_{cv}), one or more dimensions of the treatment fracture (Dim_{treatfrac}), and a vector between the control volume and the treatment fracture (vec).

76. The distributed computing system of claim 75, wherein the analytical solution further comprises uᵢ(x)=f(Dim_{cv},Dim_{treatfrac},vec,rot,geo),
where uᵢ(x) is the displacement field that comprises the at least one control point, and is a function of one or more dimensions of the control volume (Dim_{cv}), one or more dimensions of the treatment fracture (Dim_{treatfrac}), a vector between the control volume and the treatment fracture (vec), a rotation of the control volume relative to the treatment fracture (rot), and one or more geologic properties of the subterranean formation (geo).

77. The distributed computing system of claim 47, wherein the analytical solution comprises a modified Eshelby solution.

78. The distributed computing system of claim 77, wherein the modified Eshelby solution comprises one or more equations that determines the at least one control point based at least in part on a plurality of parameters that are associated with the control volume and the hydraulic fracture.

79. The distributed computing system of claim 78, wherein the plurality of parameters comprise at least two dimensions of the control volume, at least two dimensions of the hydraulic fracture, and at least three dimensions that represent a vector between the control volume and the hydraulic fracture.

80. The distributed computing system of claim 79, wherein the plurality of parameters further comprise at least three dimensions that represent an axis of rotation between the control volume and the hydraulic fracture and an angle of rotation about the axis of rotation.

81. The distributed computing system of claim 78, wherein the plurality of parameters further comprise one or more geologic characteristics of the subterranean formation.

82. The distributed computing system of claim 78, wherein at least one of the equations comprises:
$${u}_{i} ( x ) = \frac{1}{8 π ( 1 - v )} ( {ψ}_{, jli} {ϵ}_{jl}^{*} - 2 v {ϵ}_{m m}^{*} ϕ {,}_{i} - 4 ( 1 - v ) {ϵ}_{il}^{*} ϕ {,}_{i} ) , ,$$
where uᵢ(x) represents the displacement field that comprises the at least one control point, ∈* is the eigenstrain, ν is Poisson's ratio, and ψ and Φ are volume integrals that result from applying a divergence theorem to a specialization of a generalized stress-strain equation for a body force applied on a surface at a point, r′, on a point at an offset displacement, r.

83. The distributed computing system of claim 47, wherein the operation of determining, with a numerical solution executed by the one or more hardware processors, a fluid pressure change of the control volume based on the change to the at least one control point, comprises:
calculating, with the numerical solution executed by the one or more hardware processors, a pressure transfer function on the control volume based on the fluid pressure change on the control volume.

84. The distributed computing system of claim 83, wherein the pressure transfer function comprises:
Rₛᵢₘ^{l}=g^{l}({x̅^{m},x̅^{t}}^{l})=g^{l}({xᵢ^{m},xᵢ^{t}}^{l})=g^{l}({Dᵢⱼyⱼ^{m},Dᵢⱼyⱼ^{t}}^{l}),
where Rₛᵢₘ^{l} is a modeled pressure of the control volume, g^{l} is the pressure transfer function, x^{m} represents a vector that represents degrees of freedom of the control volume, x^{l} represents a vector that represents degrees of freedom of the hydraulic fracture.

85. The distributed computing system of claim 47, wherein the operation of determining, with the solver executed by the one or more hardware processors, at least one dimension of at least one of the control volume or the hydraulic fracture based at least in part on the determined fluid pressure change of the control volume, comprises: performing, with the solver, a global analysis to determine the at least one dimension of the control volume; and
performing, with the solver, a local analysis to determine the at least one dimension of the hydraulic fracture.

86. The distributed computing system of claim 85, wherein the operation of performing the global analysis comprises:
performing, with the solver, a single- or multi-objective, non-linear constrained optimization analysis to minimize at least one objective function associated with at least one fluid pressure measured by a pressure sensor in fluid communication with the control volume; and
based on minimizing the at least one objective function, determining, with the solver, the at least one dimension of the control volume.

87. The distributed computing system of claim 86, wherein the at least one objective function comprises a first objective function, and minimizing the first objective function comprises:
minimizing a difference between the at least one fluid pressure and the determined fluid pressure change of the control volume.

88. The distributed computing system of claim 87, wherein the operations further comprise assessing, with the solver, a shift penalty to the first objective function.

89. The distributed computing system of claim 47, wherein the operations further comprise minimizing, with the solver, a second objective function associated with an area of the control volume or the hydraulic fracture.

90. The distributed computing system of claim 89, wherein the operation of minimizing the second objective function comprises at least one of:
minimizing a difference between the area of the control volume and an average area of a group of control volumes that comprises the control volume; or
minimizing a difference between the area of the hydraulic fracture and an average area of a group of hydraulic fractures in a hydraulic fracturing stage group that comprises the hydraulic fracture.

91. The distributed computing system of claim 90, wherein the operations further comprise applying, with the solver, a constraint to the single- or multi-objective, non-linear constrained optimization analysis associated with at least one of a center of the control volume or a center of the hydraulic fracture.

92. The distributed computing system of claim 89, wherein the operations further comprise iterating the steps until:
an error for at least one of the first or second objective functions is less than a specified value; and
a change in the determined at least one dimension for the control volume or the hydraulic fracture from a previous iteration to a current iteration is less than the specified value.

93-138. (canceled)
